(19) United States
(12) Patent Application Publication
(10) Pub. No.: US 2002/0058409 A1
(43) Pub. Date: May 16, 2002

(54) Elimination of overhang in liner/barrier/seed layers using post-deposition sputter etch

(76) Inventors: Ching-Te Lin, Plano, TX (US); Jiong-Ping Lu, Richardson, TX (US); Asad M. Haider, Dallas, TX (US)

Correspondence Address: TEXAS INSTRUMENTS INCORPORATED, P O BOX 655474, M/S 3999, DALLAS, TX, 75265

(21) Appl. No.: 09/975,444

(22) Filed: Oct. 11, 2001

Related U.S. Application Data
(60) Provisional application No. 60/249,106, filed on Nov. 16, 2000.

(51) Int. Cl. H01L 21/4763; H01L 21/44

(52) U.S. Cl. 438/638; 438/643; 438/687

(57) ABSTRACT

A post-liner/barrier/seed deposition sputter etch is used to remove an overhang portion (111) of a physical vapor deposited (PVD) film (110, 112, 214). A PVD process typically results in a liner/barrier (110,214) or seed (112) layer having thicker overhang portion (111) at the upper corners of a trench (108), via (106), or contact (212). A post deposition sputter etch using low bias is used to reduce the thickness of the overhang portion (111) and avoid a seam in a subsequent fill process.

### FIELD OF THE INVENTION

The invention is generally related to the field of fabricating liners/barriers in contacts, vias, and copper interconnects in semiconductor devices and more specifically to the elimination of overhang in liner/barrier/seed deposition using sputter etch.

### BACKGROUND OF THE INVENTION

As the density of semiconductor devices increases, the demands on interconnect layers for connecting the semiconductor devices to each other also increases. Therefore, there is a desire to switch from the traditional aluminum metal interconnects to copper interconnects. Unfortunately, suitable copper etches for a semiconductor fabrication environment are not readily available. To overcome the copper etch problem, damascene processes have been developed.

In a conventional interconnect process, the aluminum (and any liner/barrier metals) are deposited, patterned, and etched to form the interconnect lines. Then, an interlevel dielectric (ILD) is deposited and planarized. In a damascene process, the ILD is formed first. The ILD is then patterned and etched. A thin liner/barrier material is then deposited over the structure followed by copper deposition over the liner/barrier material. Then, the copper and liner/barrier material are chemically-mechanically polished to remove the material from over the ILD, leaving metal interconnect lines. A metal etch is thereby avoided.

The most practical technique for forming copper interconnects is electrochemical deposition (ECD). In this process, after the liner/barrier material is deposited, a seed layer of copper is deposited. Then, ECD is used to deposit copper over the seed layer. Unfortunately, physical vapor deposition (PVD) processes typically used to deposit the liner/barrier and seed materials have poor step coverage. This is due to the fact that PVD processes use a line of sight technique. As a result, an overhang 18 of liner/barrier 14 and/or seed 16 material occurs at the top of a trench or via 12 as illustrated in FIG. 1. The overhang causes a severe problem during the subsequent copper ECD. Specifically, a seam occurs in the copper fill material.

This problem also occurs in forming contacts. For contacts, after the liner/barrier material is deposited, the contacts are typically filled with tungsten. An overhang in the liner/barrier material contributes to seam formation in the tungsten contact.

One proposed solution for overcoming the above problem uses a pre-sputter etch after the trench and via or contact etch, but before liner/barrier deposition. Unfortunately, this can result in high interfacial resistance due to the oxide (from the walls of the trench/via/contact) redepositing on the inside surface and bottom of the trench/via/contact. Furthermore, the contact/via profiles are not preserved which can cause resistance variation and leakage problems.

Another solution is to use a thinner liner/barrier or seed layer. Unfortunately this affects the reliability and increases the interfacial resistance due to insufficient coverage on the sidewalls and bottom of the trench/via/contact.

Another solution involves the use of CVD (chemical vapor deposition) of a titanium liner/barrier and the copper seed layer. CVD offers significantly better step coverage. Unfortunately, CVD Ti typically requires high temperature, which negatively impacts the backend thermal budget. Current CVD Cu processes have problems with layer adhesion and rough morphology.

### SUMMARY OF THE INVENTION

The invention is a post-deposition sputter etch. After depositing a PVD film, a sputter etch is performed to remove the overhang of material at the top of a trench, via, or contact. The PVD film may be a liner/barrier layer and/or a seed layer. The trench/via/contact is then filled with the appropriate material.

An advantage of the invention is providing an improved fill process using a PVD liner/barrier and sputter etch that eliminates the formation of seams in the fill material.

This and other advantages will be apparent to those of ordinary skill in the art having reference to the specification in conjunction with the drawings.

### BRIEF DESCRIPTION OF THE DRAWINGS

In the drawings:

FIG. 1 is a cross-sectional view of a prior art liner/barrier/seed process that results in an overhang of material at the top of a trench, via, or contact;

FIGS. 2A-2E are cross-sectional drawings of a copper interconnect structure formed according to the first embodiment of the invention; and

FIGS. 3A-3D are cross-sectional drawings of a contact structure formed according to a second embodiment of the invention.

### DETAILED DESCRIPTION OF THE EMBODIMENTS

Several embodiments of the invention are discussed below. The invention uses a light sputter etch with low bias to remove or reduce the overhang typically associated with a PVD liner/barrier/seed layer. The sputter etch is performed after the deposition of the liner/barrier/seed layer. No sputtering of the dielectric is performed. Therefore, redeposition of dielectric material is avoided.

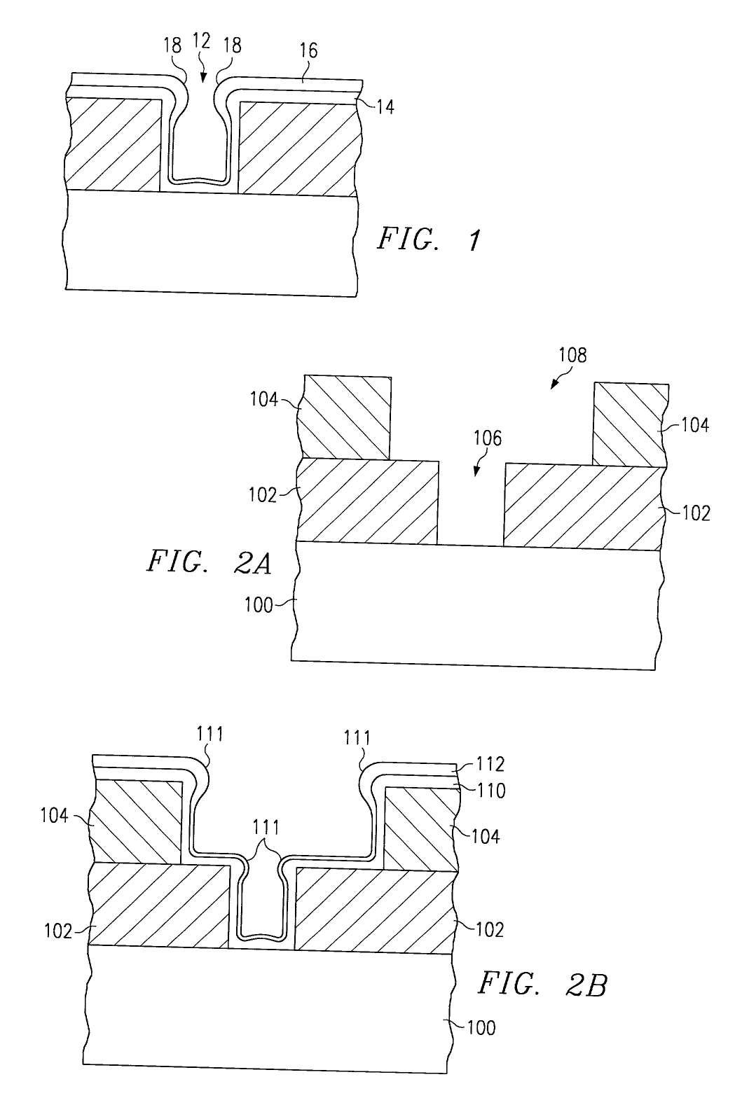

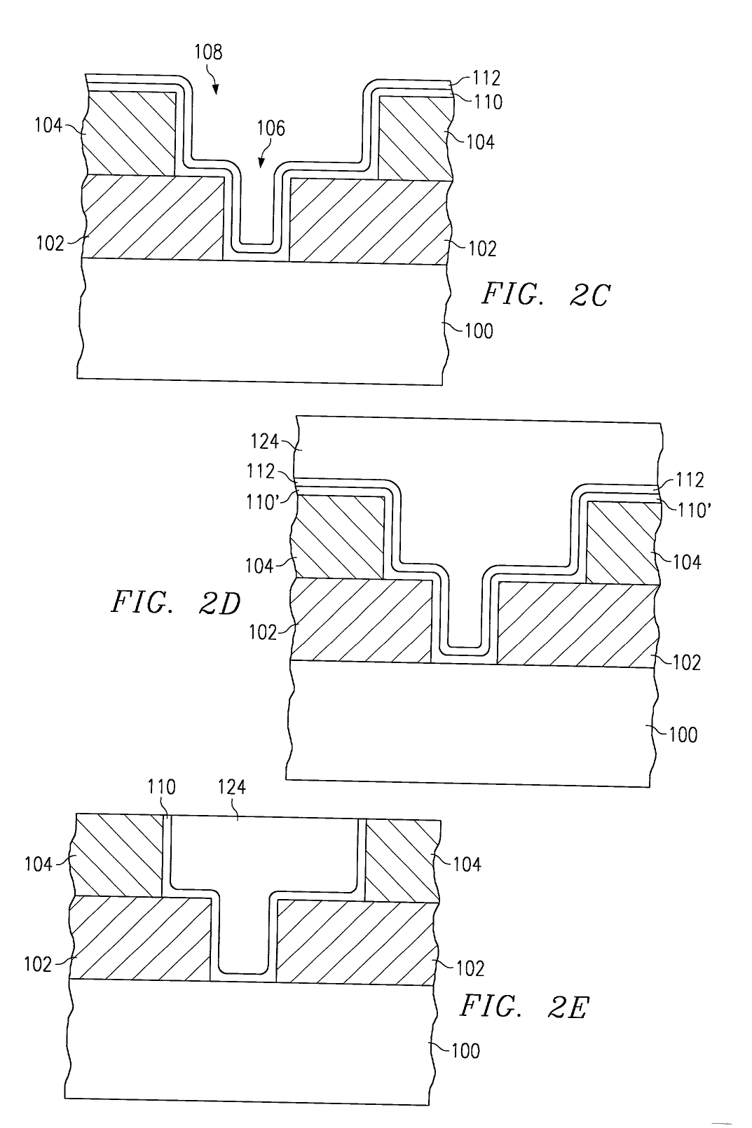

The first embodiment of the invention will now be discussed in conjunction with a dual damascene copper interconnect process. It will be apparent to those of ordinary skill in the art that the benefits of the invention may be applied to other interconnect processes in which a PVD liner/barrier is deposited over a narrow opening. The first embodiment is discussed with reference to FIGS. 2A-2E.

A semiconductor body 100 is processed through formation of trench and vias in a metal interconnect level, as shown in FIG. 2A. Semiconductor body 100 typically comprises a silicon substrate with transistors and other devices formed therein. Semiconductor body 100 also includes the pre-metal dielectric (PMD) and may include one or more metal interconnect layers.

An ILD (interlevel dielectric) 102 is formed over semiconductor body 100. IMD (intrametal dielectric) 104 is formed over ILD 102. An etchstop layer (not shown) may optionally be placed between ILD 102 and IMD 104. Suitable dielectrics for ILD 102 and IMD 104, such as silicon dioxides, fluorine-doped silicate glass (FSG), organo-silicate glass (OSG), hydrogen silesquioxane (HSQ), and combinations thereof, are known in the art. ILD 102 and IMD 104 are thick dielectric layers having a thickness in the range of 0.1 μm-1 μm.

In a copper dual damascene process, both the vias and trenches are etched in the dielectric. Via 106 is etched in ILD 102 and trench 108 is etched in IMD 104. Via 106 is used to connect to underlying metal interconnect layers. Trench 108 is used to form the metal interconnect lines.

Liner/barrier layer 110 is deposited using a PVD process over IMD 104 including in trench 108 and via 106, as shown in FIG. 2B. Liner/barrier layer 110 functions to prevent copper diffusion into the ILD and IMD layers. For example, liner/barrier layer 110 may comprise Ti or TiN. Other suitable liner/barrier materials such as Ta, TaN, TiN, TaNSi, TiNSi, MoN and WN are known in the art. Due to the nature of the PVD process, the thickness of the liner/barrier layer 110 is greater at the top of trench 108 and via 106. This is referred to as an overhang 111.

In a copper interconnect process, a copper seed layer 112 is deposited over liner/barrier layer 110. Seed layer 112 is typically deposited using a PVD process. Accordingly, overhang 111 includes excess seed material as well.

In the preferred embodiment, after the seed layer 112 is deposited, a sputter etch is performed to remove/reduce overhang 111, as shown in FIG. 2C. Alternatively, the sputter etch may be performed between the liner/barrier deposition and seed deposition steps. The sputter etch uses a low bias (e.g., 0 volt to −300 volts) to improve the film profile. By using a low bias, only the metal in the field and top corners is removed. The bottom film thickness does not change significantly and therefore, the amount of material at the bottom interface is preserved. The sputter etch is preferably performed in situ after the liner/barrier/seed deposition without breading vacuum to preserve the film's integrity.

The duration of the sputter etch is chosen such that the corners of the trench 108 or via 106 are not exposed. Sufficient liner/barrier material 110/112 remains at the corners to prevent the diffusion of copper (110) and to provide sufficient amount of conductivity during the ECD process (112).

By performing a sputter etch after the liner/barrier deposition instead of before it, the oxide re-deposition from the sidewalls of the via/trench onto the bottom of the via/trench is eliminated. Because it is the liner/barrier/seed material that is sputter etched, only liner/barrier/seed (metal) material is redeposited at the bottom of the trench/via. Redeposition of the metal does not result in high interfacial resistance as does redeposition of oxide material because of materials conductivity difference.

After the sputter etch, copper ECD is performed as shown in FIG. 2D to form copper layer 124. Because the sputter etch removes/reduces the overhang 111, no seam forms in electroplated copper layer 124 due to early closure at the tops of the trench or via. Various copper ECD processes are known in the art. In one example, a 3-step process is used. After placing the wafer in the plating solution, a current of approximately 0.75 Amps is passed through the seed layer 112 for a time on the order of 15 secs. The current is then increased to around 3 Amps for approximately 60 seconds. Final plating occurs at a current of about 7.5 Amps with the duration determined by the final desired thickness. A quick spin-rinse dry (SRD) is performed in the plating cell above the plating solution. The wafer is then transferred to the SRD cell and a post-ECD SRD is used to clean the plating residue.

Processing then continues to chemically-mechanically polish the copper layer 124 and liner/barrier 110 to form the copper interconnect, as shown in FIG. 2E. Additional metal interconnect layers may then be formed followed by packaging.

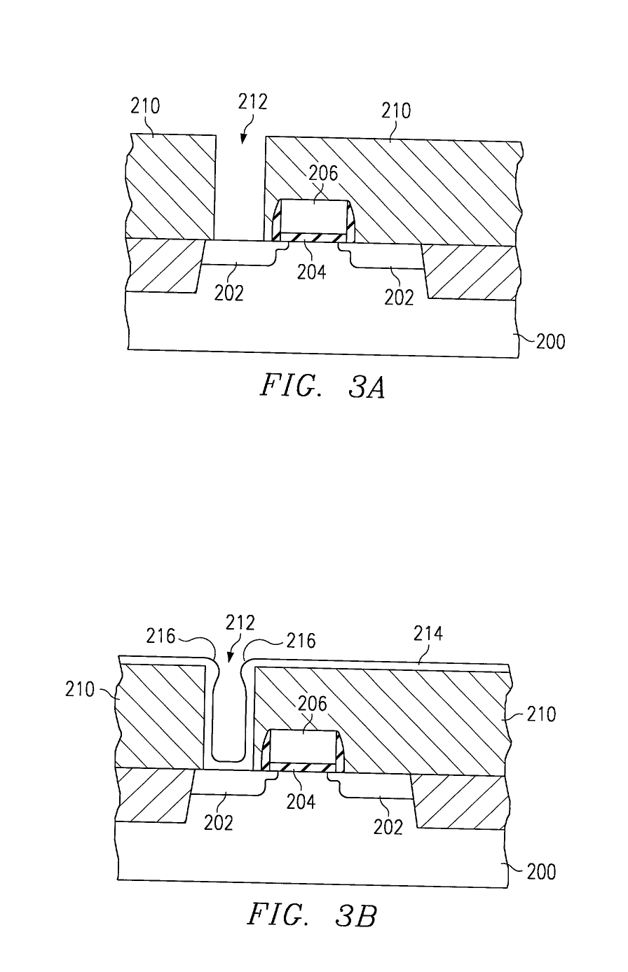

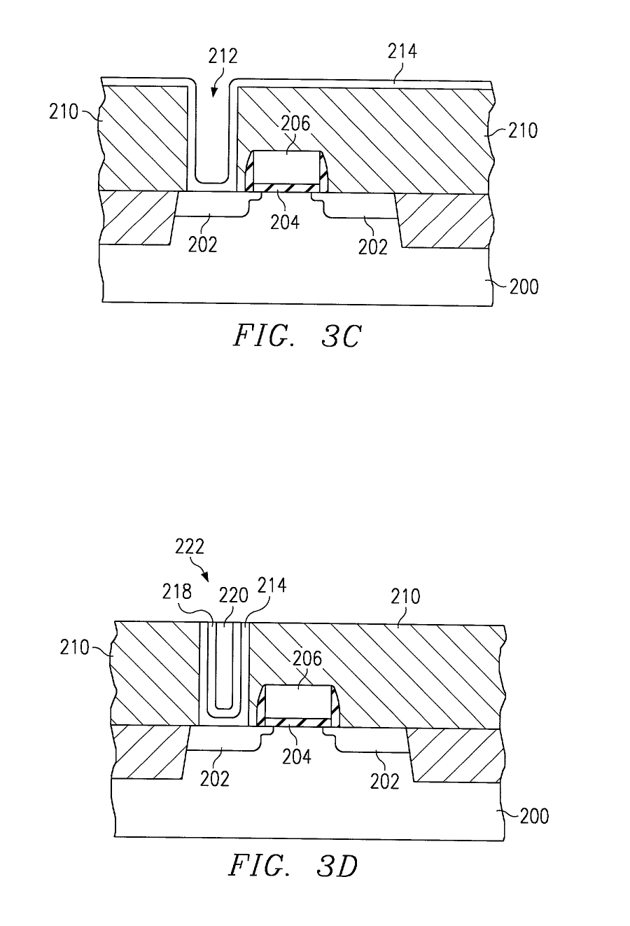

A second embodiment of the invention will now be discussed in conjunction with a process for forming a tungsten contact. Referring to FIG. 3A, a semiconductor body 200 is processed through the formation of the pre-metal dielectric (PMD) 210. Semiconductor body 200 has transistors (source/drains 202, gate dielectric 204, gate electrode 206) formed therein. Contact holes 212 are etched in PMD 210 to make contact to, for example, source/drain 202.

Referring to FIG. 3B, a liner/barrier 214 is deposited over PMD 210 using a PVD process. Liner/barrier 214 may comprise Ti. Because a PVD process is used, the portion of the liner/barrier material at the top edges of contact hole 212 is thicker and creates overhang 216.

After deposition of liner/barrier 214, a light sputter etch is performed to reduce or remove overhang 216, as shown in FIG. 3C. The sputter etch uses a low bias to improve the film profile. By using a low bias, only the liner/barrier metal in the field and top corners is removed. The bottom film thickness does not change significantly and therefore, the amount of material at the bottom interface is preserved. The sputter etch is preferably performed in situ after the liner/barrier deposition without breaking vacuum to preserve the film's integrity.

By performing a sputter etch after the liner/barrier deposition instead of before it, the oxide re-deposition from the sidewalls of the contact onto the bottom of the contact is eliminated. Because it is the liner/barrier metal that is sputter etched, only liner/barrier metal is redeposited at the bottom of the contact. Redeposition of the metal does not result in high interfacial resistance as does redeposition of oxide material.

After the sputter etch, a barrier layer 218 such as CVD/PVD TiN is deposited followed by the fill material 220. The fill material 220 and liner/barrier layer 214/218 are then chemically-mechanically polished to form a conductive plug 222, as shown in FIG. 3D. The fill material 220 typically comprises tungsten or alternative material such as CVD TiN. An overhang of the liner/barrier material 214 can cause a seam to form in the fill material 220. Because overhang 216 has been reduced or removed, seam formation is minimized in the fill material 220.

Processing then continues with the formation of metal interconnects and packaging.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

In the claims:

1. A method of fabricating an integrated circuit, comprising the steps of:
forming a dielectric layer over a semiconductor body;
forming a hole in said dielectric layer;
depositing a metal layer over said dielectric layer including in said hole using physical vapor deposition;
performing a sputter etch using a low bias after said step of depositing the metal layer; and
depositing a metal filler to fill said hole.

2. The method of claim 1, wherein said hole comprises a trench.

3. The method of claim 1, wherein said hole comprises a via.

4. The method of claim 1, wherein said hole comprises a contact.

5. The method of claim 4, wherein said metal layer comprises a liner/barrier material and said metal filler comprises tungsten.

6. The method of claim 1, wherein said metal layer comprises a liner/barrier material.

7. The method of claim 6, wherein said liner/barrier material is selected from the group consisting of Ti, TiN, Ta, TaN, WN, TiNSi, TaNSi, MoN.

8. The method of claim 1, wherein said metal layer comprises a liner/barrier material and a seed layer.

9. The method of claim 8, wherein said liner/barrier material comprises TaN and said seed layer comprises copper.

10. The method of claim 1, wherein said step of depositing a metal layer forms an overhang portion at upper corners of said hole and wherein said sputter etch step reduces a thickness of said overhang portion.

11. The method of claim 1, wherein said low bias is in the range of 0 to −300 volts.

12. A method of fabricating an integrated circuit, comprising the steps of:
forming a dielectric layer over a semiconductor body;
forming a trench in a first part of said dielectric layer;
forming a via in a second part of said dielectric layer;
depositing a liner/barrier layer over said dielectric layer including in said trench and in said via using physical vapor deposition (PVD);
performing a sputter etch using a low bias after said step of depositing a liner/barrier layer;
depositing a seed layer over said liner/barrier layer; and
depositing a copper layer over said seed layer.

13. The method of claim 12, wherein said step of depositing a seed layer comprises PVD and occurs prior to said step of performing a sputter etch.

14. The method of claim 12, wherein said steps of forming the liner/barrier layer and forming the seed layer create an overhang portion of liner/barrier and seed material and wherein said sputter etch step reduces thickness of said overhang portion.

15. The method of claim 12, wherein said liner/barrier layer comprises a material selected from the group consisting of Ti, TiN, Ta, TaN, TiNSi, WN, TaNSi, MoN.

16. The method of claim 12, wherein said low bias is in the range of 0 to −300 volts.

17. A method of fabricating an integrated circuit, comprising the steps of:
forming a pre-metal dielectric (PMD) layer over a semiconductor body;
forming a contact hole in said PMD layer;
depositing a liner layer over said PMD layer including in said contact hole using physical vapor deposition, wherein said liner layer has an overhang portion at a top of said contact hole;
performing a sputter etch using a low bias to at least reduce a thickness of said overhang portion;
depositing a barrier layer over said liner layer; and
depositing a metal filler to fill said contact hole.

18. The method of claim 17, wherein said step of depositing a barrier layer comprises PVD and occurs prior to said step of performing a sputter etch.

19. The method of claim 17, wherein said metal filler comprises tungsten.

20. The method of claim 17, wherein said metal filler comprises CVD TiN.

21. The method of claim 17, wherein said liner layer comprises Ti and barrier layer comprises TiN.

22. The method of claim 17, wherein said low bias is in the range of 0 to −300 volts.
